(19) United States
(12) Patent Application Publication
(10) Pub. No.: US 2022/0415216 A1
(43) Pub. Date: Dec. 29, 2022

(54) DISPLAY DEVICE AND TILED DISPLAY DEVICE INCLUDING THE SAME

(71) Applicant: Samsung Display Co., LTD., Yongin-si (KR)

(72) Inventors: Hyun Jin MAENG, Seoul (KR); Jun Hee SON, Asan-si (KR); Man Soo KIM, Hwaseong-si (KR); Ju Hee KIM, Bucheon-si (KR); Jee Na LEE, Anyang-si (KR)

(21) Appl. No.: 17/698,761

(22) Filed: Mar. 18, 2022

(30) Foreign Application Priority Data
Jun. 25, 2021 (KR) 10-2021-0082978

(51) Int. Cl. G09F 9/302; G09G 3/20

(52) U.S. Cl. CPC G09F 9/3026; G09G 3/2096; G09G 2300/026

(57) ABSTRACT

A display device comprises a display panel comprising a base part, and a display layer on an upper surface of the base part, a buffer part at an edge of, beneath, and having a side surface that is aligned with a side surface of, the display panel, a lower frame inside the buffer part, in plan view, beneath the display panel, and including a support part for supporting the display panel, and a pad part beneath a lower surface of the base part and electrically connected to the display layer.

### CROSS-REFERENCE TO RELATED APPLICATION

This application claims priority to, and the benefit of, Korean Patent Application No. 10-2021-0082978 filed on Jun. 25, 2021, in the Korean Intellectual Property Office, and all the benefits accruing therefrom, the contents of which in its entirety are herein incorporated by reference.

### BACKGROUND

### 1. Field

The present disclosure relates to a display device and a tiled display device including the same.

### 2. Description of the Related Art

As the information society develops, the demand for display devices for displaying images has increased and diversified. For example, display devices have been applied to various electronic devices, such as smartphones, digital cameras, laptop computers, navigation devices, and smart televisions. The display devices may be flat panel display devices, such as liquid crystal display devices, field emission display devices, or organic light emitting display devices. Among such flat panel display devices, a light emitting display device may display an image without a backlight unit providing light to a display panel because each of pixels of the display panel includes a light emitting element that may emit light by itself.

When the display device is manufactured in a large size, a defect rate of the light emitting element may increase due to an increase in the number of pixels, and productivity or reliability may decrease. To solve such a problem, a tiled display device may realize a screen having a large size by connecting a plurality of display devices having a relatively small size to each other. The tiled display device may include boundary portions called seams between the plurality of display devices due to non-display areas or bezel areas of each of the plurality of display devices adjacent to each other. When one image is displayed on the entire screen, the boundary portions between the plurality of display devices give a sense of discontinuity to the entire screen to decrease a degree of immersion of the image.

### SUMMARY

Aspects of the present disclosure provide a display device, or a tiled display device including a display device, in which a likelihood of damage to a display panel is reduced or prevented by locating a buffer part aligned with a side surface of the display panel at a lower edge of the display panel.

Aspects of the present disclosure also provide a display device, or a tiled display device including a display device, having improved heat dissipation by locating a buffer part completely covering a lower surface of a display panel at a lower edge of the display panel.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the disclosure, a display device comprises a display panel comprising a base part, and a display layer on an upper surface of the base part, a buffer part at an edge of, beneath, and having a side surface that is aligned with a side surface of, the display panel, a lower frame inside the buffer part, in plan view, beneath the display panel, and including a support part for supporting the display panel, and a pad part beneath a lower surface of the base part and electrically connected to the display layer.

The side surface of the buffer part may be aligned with a side surface of the base part.

The display panel may further include an encapsulation layer above the base part and covering the display layer, wherein the side surface of the buffer part is aligned with a side surface of the encapsulation layer.

The display panel may further include an encapsulation layer above the base part and covering the display layer, wherein the encapsulation layer covers a side surface of the base part, and wherein the side surface of the buffer part is aligned with a side surface of the encapsulation layer.

The side surface of the base part may be inside the side surface of the buffer part in plan view.

The buffer part may be on an outer side surface of the lower frame.

The lower frame may further include a sidewall part extending from the support part in a downward direction.

The buffer part and the lower frame may cover the lower surface of the base part at an edge of the base part.

The buffer part and the lower frame may include a same material.

The buffer part and the lower frame may be formed integrally with each other.

The base part may include polyimide, wherein the buffer part has elasticity along a horizontal direction that is substantially perpendicular to a thickness direction of the display panel.

The display device may further include a flexible film under the display panel and electrically connected to the pad part, and a circuit board electrically connected to the flexible film and supporting a driving circuit driving the display layer.

The pad part may be inside the lower frame.

The display layer may include a connection line on the base part and exposed on a lower surface of the display layer, wherein the display panel further includes a conductive part in an opening penetrating through the base part, and electrically connected to the connection line, and wherein the pad part is electrically connected to the connection line through the conductive part.

The opening may overlap the connection line exposed on the lower surface of the display layer.

According to one or more embodiments of the disclosure, a tiled display device includes a lower plate, and a plurality of display devices on the lower plate and including a display panel including a base part, and a display layer on an upper surface of the base part, a buffer part at an edge of the display panel, beneath the display panel, and having a side surface that is aligned with a side surface of the display panel, a lower frame inside the buffer part under the display panel, and including a support part for supporting the display panel, and a pad part on a lower surface of the base part, and electrically connected to the display layer.

The plurality of display devices may include a first display device and a second display device adjacent to each other, wherein the buffer part of the first display device and the buffer part of the second display device are in contact with each other, and wherein the display panel of the first display device and the display panel of the second display device are in contact with each other.

The side surface of the buffer part may be aligned with a side surface of the base part.

The display panel may further include an encapsulation layer on the base part and covering the display layer, wherein the side surface of the buffer part is aligned with a side surface of the encapsulation layer.

The buffer part may be on an outer side surface of the lower frame, wherein the buffer part and the lower frame cover the lower surface of the base part at an edge of the base part.

In a display device and a tiled display device including the same, according to the present disclosure, the display device may include the display panel, and the buffer part located along the edge of the display panel under the display panel. The base part of the display panel and the buffer part are substantially simultaneously or concurrently cut through the same cutting process, such that a side surface of the base part and the side surface of the buffer part may be aligned with each other. Therefore, an impact, which is between adjacent display devices generated in a tiling process of aligning and fixing the plurality of display devices, among processes of manufacturing the tiled display device, is dispersed to the buffer part as well as the base part, such that damage to the base part due to the impact may be reduced or minimized.

In addition, in a display device and a tiled display device including the same, according to the present disclosure, the lower surface of the base part positioned at the edge of the base part is covered by the buffer part, such that an area in which the lower surface of the base part is exposed to the outside is reduced or minimized, and thus, heat dissipation of the display device may be improved. Therefore, reliability of the tiled display device may be improved.

The aspects of the present disclosure are not limited to the aforementioned aspects, and various other aspects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a plan view illustrating a tiled display device according to one or more embodiments;

FIG. 2 is a schematic plan view illustrating an area of the tiled display device according to one or more embodiments;

FIG. 3 is a schematic cross-sectional view of the tiled display device according to one or more embodiments;

FIG. 4 is a schematic cross-sectional view of a display device according to one or more embodiments;

FIG. 5 is a bottom perspective view for describing a layout between a base part, a lower frame, and a buffer part according to one or more embodiments;

FIG. 6 is a bottom view for describing the layout between the base part, the lower frame, and the buffer part according to one or more embodiments;

FIG. 7 is a cross-sectional view of a display panel taken along the line I-I′ of FIG. 2;

FIG. 8 is a schematic perspective view of a light emitting element according to one or more embodiments;

FIG. 9 is an enlarged view of area B of FIG. 7;

FIG. 10 is a schematic cross-sectional view illustrating a relative layout of the display panel, a pad part, a connection line, and a conductive part at an edge of the display panel according to one or more embodiments;

FIG. 11 is an enlarged cross-sectional view illustrating an example of area A of FIG. 4;

FIG. 12 is a schematic cross-sectional view illustrating display devices located adjacent to each other in the tiled display device according to one or more embodiments;

FIGS. 13 to 17 are views illustrating manufacturing processes of the display device of FIG. 11;

FIG. 18 is an enlarged cross-sectional view illustrating another example of area A of FIG. 4;

FIG. 19 is an enlarged cross-sectional view illustrating still another example of area A of FIG. 4; and

FIG. 20 is an enlarged cross-sectional view illustrating still another example of area A of FIG. 4.

### DETAILED DESCRIPTION

In the following description, for the purposes of explanation, numerous specific details are set forth to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, well-known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation, not as terms of degree, and thus are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or overly formal sense, unless clearly so defined herein.

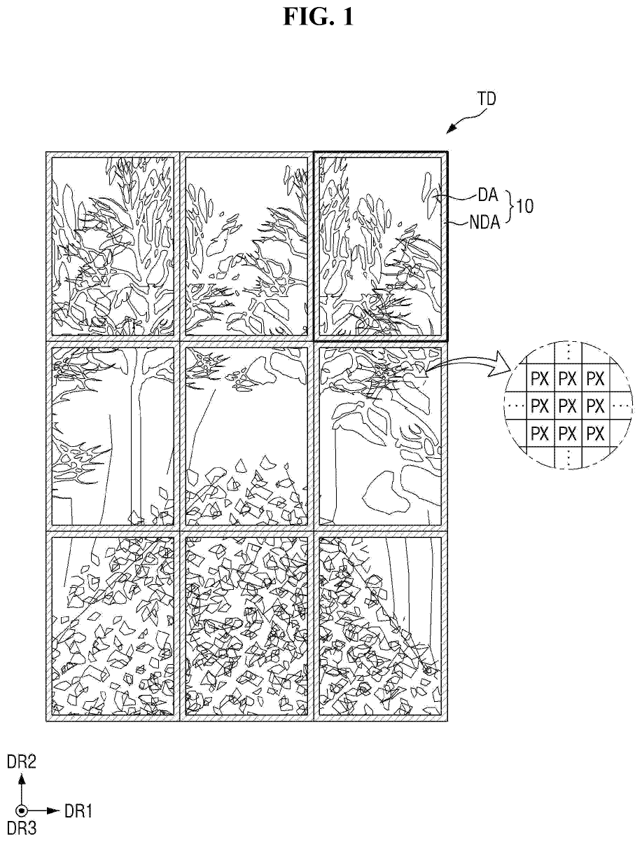

FIG. 1 is a plan view illustrating a tiled display device according to one or more embodiments.

Referring to FIG. 1, a tiled display device TD displays a moving image or a still image. The tiled display device TD may refer to all electronic devices that provide a display screen. For example, televisions, laptop computers, monitors, billboards, the Internet of Things (IoT), mobile phones, smartphones, tablet personal computers (PCs), electronic watches, smartwatches, watch phones, head mounted displays, mobile communication terminals, electronic organizers, electronic books, portable multimedia players (PMPs), navigation devices, game machines, digital cameras, camcorders, and the like, which provide display screens, may be included in the tiled display device TD.

Hereinafter, a first direction DR1, a second direction DR2, and a third direction DR3 are defined in the drawings for describing the tiled display device TD. The first direction DR1 and the second direction DR2 may be directions perpendicular to each other in one plane. The third direction DR3 may be a direction perpendicular to the plane in which the first direction DR1 and the second direction DR2 are positioned. The third direction DR3 is perpendicular to each of the first direction DR1 and the second direction DR2. Hereinafter, in one or more embodiments for describing the tiled display device TD, the third direction DR3 refers to a thickness direction (or a display direction) of the tiled display device TD.

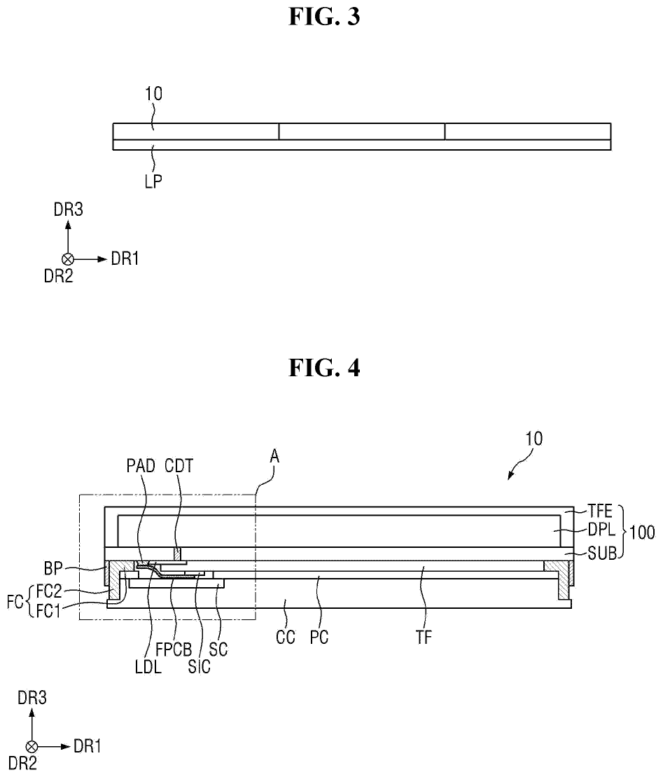

For describing structures of the tiled display device TD and a display device 10 in the present disclosure, unless otherwise stated, “upper portion” refers to one side in the third direction DR3 and refers to a side on which a display layer DPL (see FIG. 4) is located with respect to a base part SUB (see FIG. 4) to be described later, and “upper surface” refers to a surface facing one side in the third direction DR3. In addition, “lower portion” refers to the other side in the third direction DR3 opposite to the aforementioned one side in the third direction DR, and “lower surface” refers to a surface facing the other side in the third direction DR3.

The tiled display device TD may have a rectangular shape, in plan view, having short sides in the first direction DR1 and long sides in the second direction DR2. The tiled display device TD may have an overall planar shape, but is not limited thereto.

The tiled display device TD according to one or more embodiments may include a plurality of display devices 10.

The plurality of display devices 10 may be arranged in a matrix shape. The plurality of display devices 10 may be arranged along the first direction DR1 and the second direction DR2 in plan view. FIG. 1 has illustrated a case where the plurality of display devices 10 are arranged in a 3×3 matrix shape, but the number of display devices 10 and an arrangement of the plurality of display devices 10 are not limited thereto.

The plurality of display devices 10 may be connected to each other in the first direction DR1 or the second direction DR2, and the tiled display device TD may have a corresponding shape. FIG. 1 has illustrated a case where arrangement directions of the plurality of display devices 10 coincide with the first direction DR1 and the second direction DR2, which are respectively extension directions of the short sides and the long sides of the tiled display device TD, but the present disclosure is not limited thereto, and the arrangement directions of the display device 10 and the extension directions of the long sides and the short sides of the tiled display device TD may also be inclined with an inclination (e.g., a predetermined inclination).

Each of the plurality of display devices 10 may have a rectangular shape, in plan view, having short sides in the first direction DR1 and long sides in the second direction DR2. The plurality of display devices 10 may be located with long sides or short sides connected to each other. Some of the plurality of display devices 10 included in the tiled display device TD may be located at an edge of the tiled display device TD to form at least a portion of a corresponding side of the tiled display device TD. Other display devices 10 of the plurality of display devices 10 included in the tiled display device TD may be located at respective corner portions of the tiled display device TD to form two respective adjacent sides of the tiled display device TD. The other display devices 10 of the plurality of display devices 10 included in the tiled display device TD may be located inside the tiled display device TD, and may be surrounded by other display devices 10.

Each of the plurality of display devices 10 includes a display panel providing a display screen. Examples of the display panel include an inorganic light emitting diode display panel, an organic light emitting display panel, a quantum dot light emitting display panel, a plasma display panel, a field emission display panel, and the like. Hereinafter, a case where an inorganic light emitting diode display panel is applied as an example of the display panel will be described by way of example, but the present disclosure is not limited thereto, and the same technical idea may be applied to other display panels if applicable.

The display device 10 may include a display area DA and a non-display area NDA. The display area DA may include a plurality of pixels PX to display an image. The non-display area NDA may be located around the display area DA to surround the display area DA, and may not display an image.

The tiled display device TD may have an overall planar shape, but is not limited thereto. In one or more embodiments, the tiled display device TD may have a three-dimensional shape to provide a three-dimensional effect to a user. As an example, when the tiled display device TD has the three-dimensional shape, at least some of the plurality of display devices 10 may have a curved shape. As another example, the plurality of display devices 10 have a planar shape and are connected to each other at an angle (e.g., a predetermined angle), such that the tiled display device TD may have a three-dimensional shape.

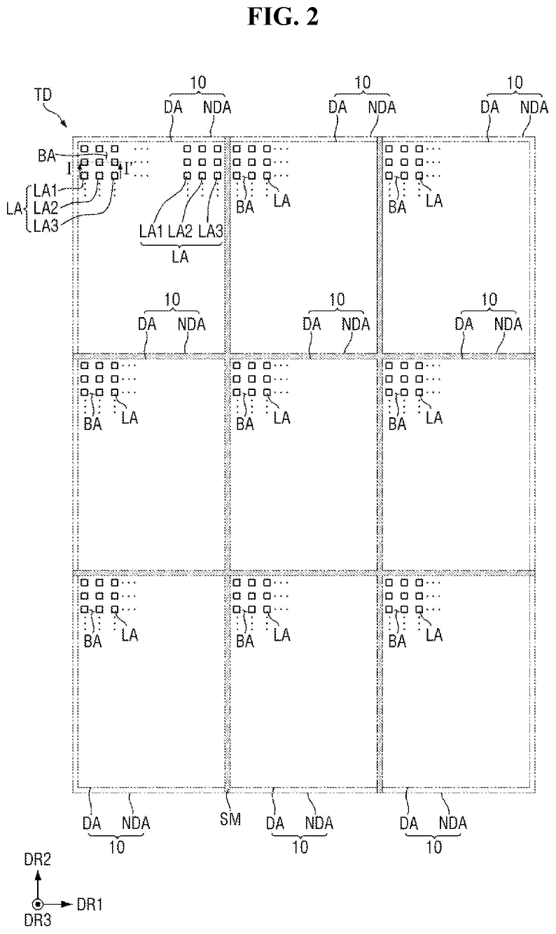

FIG. 2 is a schematic plan view illustrating an area of the tiled display device according to one or more embodiments.

Referring to FIGS. 1 and 2, as described above, each of the plurality of display devices 10 included in the tiled display device TD may include the display area DA and the non-display area NDA.

A shape of the display area DA may follow the shape of the display device 10. For example, the shape of the display area DA may have a rectangular shape in plan view, similar to the overall shape of the display device 10. The display area DA may occupy substantially the center of the display device 10.

The non-display area NDA may be located around the display area DA. The non-display area NDA may completely or partially surround the display area DA.

The tiled display device TD may further include boundary areas SM including areas in which adjacent display devices 10 are coupled to each other. The boundary areas SM may be located between the display areas DA of the adjacent display devices 10. The boundary areas SM may include the non-display areas NDA of each of the adjacent display devices 10. A plurality of adjacent display devices 10 may be in contact with each other, and abut on each other, in the boundary areas SM.

Intervals between the display areas DA of each of the plurality of display devices 10 may be too small for the boundary areas SM between the plurality of display devices 10 to be recognized by the user. In addition, an external light reflectivity of the display areas DA of each of the plurality of display devices 10 may be substantially the same as an external light reflectivity of the boundary areas SM between the plurality of display devices 10. Accordingly, the tiled display device TD may remove a sense of discontinuity between the plurality of display devices 10, and may improve a degree of immersion of an image by reducing or preventing visibility of the boundary areas SM between the plurality of display devices 10 to a user.

As described above, the display area DA may include a plurality of pixels PX. The plurality of pixels PX may be arranged in a matrix direction. A shape of each pixel PX may be a rectangular shape or a square shape in plan view. In one or more embodiments, each pixel PX may include a plurality of light emitting elements made of inorganic particles, but is not limited thereto.

Each of the plurality of pixels PX may include a light emission area LA defined by a bank, and a light blocking area BA around the light emission area LA.

The light emission area LA may be area in which light generated from a light emitting element of a display device 10 (to be described later) is provided to the outside of the display device 10, and the light blocking area BA may be an area in which the light generated from the light emitting element of the display device 10 is not provided to the outside of the display device 10.

The light emission area LA may include first to third light emission areas LA1, LA2, and LA3. The first to third light emission areas LA1, LA2, and LA3 may emit light having a peak wavelength (e.g., a predetermined peak wavelength) to the outside of the display device 10. The first light emission area LA1 may emit light of a first color, the second light emission area LA2 may emit light of a second color, and the third light emission area LA3 may emit light of a third color. For example, the light of the first color may be red light having a peak wavelength in the range of about 610 nm to about 650 nm, the light of the second color may be green light having a peak wavelength in the range of about 510 nm to about 550 nm, and the light of the third color may be blue light having a peak wavelength in the range of about 440 nm to about 480 nm, but the present disclosure is not limited thereto.

The first to third light emission areas LA1, LA2, and LA3 may be sequentially and repeatedly located in the display area DA along the first direction DR1.

The light blocking areas BA may be located to surround a plurality of light emission areas LA: LA1, LA2, and LA3. The light blocking area BA of each pixel PX may be in contact with the light blocking area BA of the neighboring pixel PX. The light blocking areas BA of the neighboring pixels PX may be connected to each other as one area, and furthermore, the light blocking areas BA of all pixels PX may be connected to each other as one area, but the present disclosure is not limited thereto. The light emission areas LA: LA1, LA2, and LA3 of each of the neighboring pixels PX may be divided by the light blocking areas BA.

FIG. 3 is a schematic cross-sectional view of the tiled display device according to one or more embodiments.

Referring to FIGS. 2 and 3, the tiled display device TD according to one or more embodiments includes the plurality of display devices 10 and a lower plate LP.

The lower plate LP may serve to provide an area in which the plurality of display devices 10 are located and to support the plurality of display devices 10. A planar shape of the lower plate LP may follow the planar shape of the tiled display device TD. In one or more embodiments in which the tiled display device TD has the rectangular shape, in plan view, having the short sides in the first direction DR1 and the long sides in the second direction DR2, the lower plate LP may have a rectangular shape, in plan view, having short sides in the first direction DR1 and long sides in the second direction DR2. In one or more embodiments, a fastening member capable of fixing the plurality of display devices 10 or a moving member capable of moving each of the plurality of display devices 10 in the first direction DR1 and/or the second direction DR2 to align the plurality of display devices 10 on the lower plate LP may be further located on the lower plate LP.

The plurality of display devices 10 may be located on the lower plate LP. The plurality of display devices 10 may be fixed onto one surface of the lower plate LP through the fastening member.

The plurality of display devices 10 may be arranged in a matrix shape on the lower plate LP. The plurality of display devices 10 may be located so that side surfaces thereof are in contact with each other on the lower plate LP. The display devices 10 are located so that the side surfaces thereof are in contact with each other on the lower plate LP, such that visibility of the boundary areas SM between the display areas DA of adjacent display devices 10 to the user may be reduced or minimized. That is, the plurality of display devices 10 may be aligned to be as close to each other as possible on the lower plate LP so that the boundary areas SM, which are located between the display areas DA of the respective display devices 10, and in which the image is not displayed, are reduced or minimized and are not visually recognized by the user.

FIG. 4 is a schematic cross-sectional view of a display device according to one or more embodiments.

Referring to FIG. 4, a display device 10 according to one or more embodiments may include a display panel 100, a pad part PAD, a flexible film FPCB, a circuit board SIC, a lower frame FC, and a buffer part BP. The display device 10 may further include a heat dissipation member TF, a lower protective layer PC, a protective case SC, and a bottom chassis CC.

The display panel 100 according to one or more embodiments may include a base part SUB, a display layer DPL, an encapsulation layer TFE, the pad part PAD, a lead line LDL, and a conductive part CDT.

The base part SUB may serve to support the display layer DPL. The base part SUB may include an organic material. In one or more embodiments, the base part SUB may include polyimide (PI). That is, the base part SUB may be a polyimide substrate. However, the present disclosure is not limited thereto, and the base part SUB may also include an insulating material such as glass, quartz, or a polymer resin.

The base part SUB may include an opening penetrating through the base part SUB. The conductive part CDT electrically connected to the display layer DPL may be located in the opening penetrating through the base part SUB.

The display layer DPL may be located on one surface (upper surface in FIG. 4) of the base part SUB. The display layer DPL may be a layer including a plurality of pixels PX to display an image.

The encapsulation layer TFE may be located on the display layer DPL. The encapsulation layer TFE may completely cover an upper surface and side surfaces of the display layer DPL. In one or more embodiments, the encapsulation layer TFE may be located on the upper surface of the base part SUB exposed by the display layer DPL, but may be omitted from side surfaces of the base part SUB. For example, the encapsulation layer TFE may include at least one inorganic film to reduce or prevent permeation of oxygen or moisture. In addition, the encapsulation layer TFE may include at least one organic film to protect the display layer DPL from foreign matters such as dust.

The pad part PAD may be located on the other surface (lower surface in FIG. 4) of the base part SUB. The pad part PAD may be located on the lower surface of the base part SUB, and may be electrically connected to the conductive part CDT through the lead line LDL. The pad part PAD may receive various voltages or signals from the flexible film FPCB, and may supply the received voltages or signals to the display layer DPL through the lead line LDL and the conductive part CDT.

The lead line LDL may be located on the other surface (lower surface in FIG. 4) of the base part SUB. The lead line LDL may be located between the conductive part CDT, which is located in the opening penetrating through the base part SUB, and the pad part PAD to electrically connect the conductive part CDT and the pad part PAD to each other. For example, one end of the lead line LDL is in contact with the conductive part CDT, and the other end of the lead line LDL is in contact with the pad part PAD, so that the conductive part CDT and the pad part PAD may be electrically connected to each other.

The heat dissipation member TF may be located on the other surface (lower surface in FIG. 4) of the base part SUB. The heat dissipation member TF may cover a portion of the lower surface of the base part SUB under the base part SUB. For example, the heat dissipation member TF may be located in a central area of the base part SUB excluding an area of the base part SUB in which the pad part PAD is located. The heat dissipation member TF might not be located at an edge of the base part SUB. The heat dissipation member TF might not overlap a lower frame FC and a buffer part BP, which will be described later, in the third direction DR3.

The heat dissipation member TF may be located to cover the lower surface of the base part SUB under the base part SUB, and may absorb heat generated from the display layer DPL or the circuit board SIC, and then may dissipate the heat to the outside in plan view. Accordingly, heat dissipation efficiency of the display device 10 may be improved. For example, the heat dissipation member TF may include a graphite layer or a layer including a carbon nanotube or the like, but is not limited thereto.

The lower frame FC may be located on the other surface (lower surface in FIG. 4) of the base part SUB. The lower frame FC may be located along the edge of the base part SUB under the base part SUB. The base part SUB may support the display panel 100, and may provide a space in which a plurality of members located under the display panel 100 are located.

The lower frame FC may include a support part FC1 supporting the display panel 100, and a sidewall part FC2 bent from the support part FC1. A detailed description for the lower frame FC will be provided later.

The buffer part BP may be located on the other surface (lower surface in FIG. 4) of the base part SUB. The buffer part BP may be located along the edge of the base part SUB under the base part SUB. The buffer part BP may be located to surround the sidewall part FC2 of the lower frame FC. A detailed description for the buffer part BP will be provided later.

The flexible film FPCB may be located under the display layer DPL. One end of the flexible film FPCB may be attached to the pad part PAD using an anisotropic conductive film under the display layer DPL. The other end of the flexible film FPCB may be attached to a lower surface of the circuit board SIC under the display layer DPL. The pad part PAD and the circuit board SIC may be electrically connected to each other through the flexible film FPCB. The flexible film 350 may be a flexible film that may be bent.

A driving circuit for driving the display layer DPL may be attached to the circuit board SIC, and the circuit board SIC may be a printed circuit board (PCB). The flexible film FPCB may transmit a driving signal of the driving circuit attached to the circuit board SIC to the display layer DPL. The driving circuit may receive control signals and power voltages applied through the circuit board SIC, and may generate and output signals and voltages for driving the display panel 100. For example, the driving circuit may be formed as an integrated circuit (IC), and may be attached onto the circuit board SIC.

The lower protective layer PC and the protective case SC may be located in an area surrounded by the sidewall part FC2 of the lower frame FC.

For example, the lower protective layer PC may be located under the display panel 100 and the heat dissipation member TF. The lower protective layer PC may also be located under the support part FC1 of the lower frame FC. The lower protective layer PC may be located to expose the pad part PAD, the flexible film FPCB, and the circuit board SIC. For example, the lower protective layer PC may cover a lower portion of the display panel 100 except for an area in which the pad part PAD, the flexible film FPCB, and the circuit board SIC are located. The lower protective layer PC may serve to protect the display panel 100 located above the lower protective layer PC. The lower protective layer PC may include a material having rigidity (e.g., a predetermined rigidity). For example, the lower protective layer PC may include a metal material such as iron, copper, or aluminum, or alloys thereof, but is not limited thereto.

The protective case SC may be located under the lower protective layer PC. The protective case SC may overlap the area in which the pad part PAD, the flexible film FPCB, and the circuit board SIC are located, with respect to the third direction DR3. The protective case SC may serve to protect the pad part PAD, the flexible film FPCB, and the circuit board SIC exposed by the lower protective layer PC under the lower protective layer PC.

The bottom chassis CC may be located under the protective case SC and the lower protective layer PC. The bottom chassis CC may be located under the sidewall part FC2 of the lower frame FC. The bottom chassis CC may be located under the protective case SC and the lower protective layer PC, and may serve to support and accommodate the display panel 100 and a plurality of members located under the display panel 100.

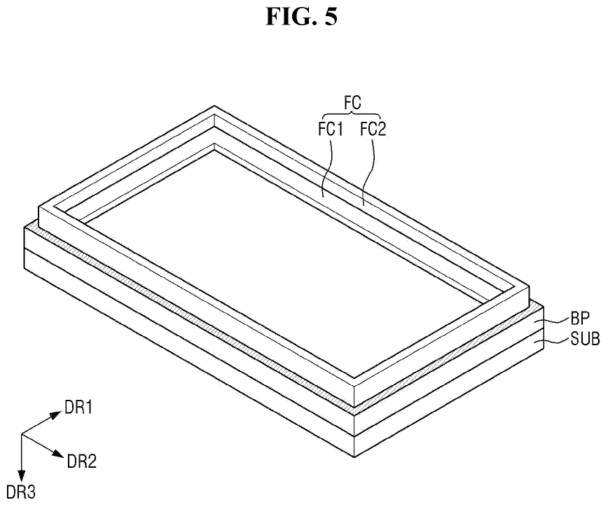

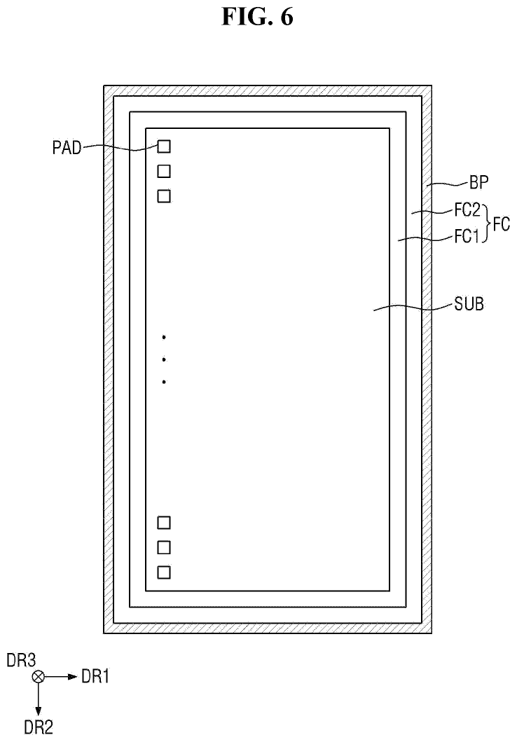

FIG. 5 is a bottom perspective view for describing a layout of a base part, a lower frame, and a buffer part according to one or more embodiments. FIG. 6 is a bottom view for describing the layout of the base part, the lower frame, and the buffer part according to one or more embodiments.

Referring to FIGS. 4 to 6, the lower frame FC may be located at an edge portion of the base part SUB under the base part SUB. The lower frame FC may be located to surround the edge of, or to be at a perimeter of, the base part SUB, and may have a frame shape in plan view. The lower frame FC may support the base part SUB under the base part SUB, and may provide a space in which a plurality of lower members located under the display panel 100 of the display device 10 are located.

The lower frame FC may include the support part FC1 supporting the base part SUB and the sidewall part FC2 extending downward from the support part FC1.

The support part FC1 may be located on the lower surface of the base part SUB. The support part FC1 may be located at a lower edge portion of the base part SUB, but may be omitted from a central area of the base part SUB. The support part FC1 may not overlap a plurality of pad parts PAD located on the lower surface of the base part SUB, with respect to the third direction DR3. The support part FC1 supports the edge of the display panel 100 under the base part SUB, and thus, may serve to help a shape of the display panel 100 to be stably maintained even though the base part SUB includes a material such as polyimide (PI).

The sidewall part FC2 may be bent downward from the support part FC1, and may extend in a downward direction (e.g., a direction opposite to the third direction DR3). The sidewall part FC2 may extend from an outer side end of both ends of the support part FC1. The support part FC1 may be positioned inside the sidewall part FC2 in plan view.

The lower frame FC may include a material having rigidity (e.g., a predetermined rigidity) to support the display panel 100, and may stably provide the space in which the plurality of lower members located under the display panel 100 are located. For example, the lower frame FC may include a metal material such as iron, copper, or aluminum, or alloys thereof, but is not limited thereto.

The buffer part BP may be located at the edge portion of the base part SUB under the base part SUB. The buffer part BP may be located to surround the lower frame FC (e.g., in plan view) under the base part SUB. The buffer part BP may be located to surround the lower frame FC, and may have a frame shape in plan view.

The buffer part BP may be located on the lower surface of the base part SUB. Accordingly, an upper surface of the buffer part BP and an upper surface of the lower frame FC may be located on the same plane, and the upper surface of the buffer part BP and the upper surface of the lower frame FC may be positioned on the lower surface of the base part SUB.

The buffer part BP might not overlap the lower frame FC in the third direction DR3. The buffer part BP may be located to surround the sidewall part FC2 of the lower frame FC, and may be located outside the sidewall part FC2. The buffer part BP may be located on (e.g., may contact) a side surface of the sidewall part FC2 of the lower frame FC. In one or more embodiments, the buffer part BP may expose a portion of the side surface of the sidewall part FC2.

The buffer part BP may serve to protect the display panel 100 by absorbing an impact generated between the display devices 10 when being located adjacent to each other in a tiling process of aligning and fixing the plurality of display devices 10 among processes of manufacturing the tiled display device TD and applied to a side portion of the display panel 100.

In one or more embodiments, the buffer part BP may include a material having elasticity (e.g., a predetermined elasticity). The buffer part BP may have elasticity in a horizontal direction (e.g., the first direction DR1, the second direction DR2, and/or therebetween) that is perpendicular to the thickness direction of the display device 10 or the display panel 100. For example, the buffer part BP may be formed of a polymer resin such as silicone, polyurethane, polycarbonate, polypropylene, or polyethylene, or may include a material having elasticity, such as a sponge formed by foaming rubber, a urethane-based material, or an acrylic-based material. Because the buffer part BP includes the material having the elasticity, the buffer part BP having the elasticity may absorb the impact generated in the tiling process of aligning and fixing the plurality of display devices 10 among the processes of manufacturing the tiled display device TD and applied between the base parts SUB of the display devices 10 to reduce or prevent the likelihood of damage to the base part SUB due to the impact.

In some other embodiments, the buffer part BP may include a material having rigidity that is greater than that of a material included in the base part SUB. Because the buffer part BP includes the material having the rigidity greater than that of the material included in the base part SUB, the impact generated in the tiling process of aligning and fixing the plurality of display devices 10 among the processes of manufacturing the tiled display device TD and applied between the base parts SUB of the display devices 10 may also be dispersed to the buffer part BP, such that damage to the base part SUB due to the impact may be reduced or prevented.

Concentration on the edge of the base part SUB of the impact generated between the display devices 10, and also applied to the side portion of the display panel 100, may be reduced or prevented. Accordingly, damage to the display panel 100 may be reduced or minimized.

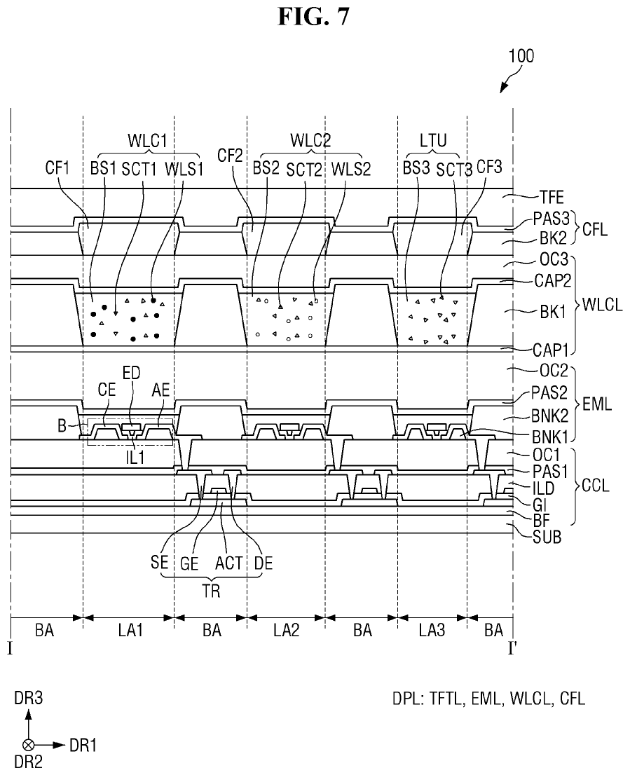

FIG. 7 is a cross-sectional view of a display panel taken along the line I-I′ of FIG. 2.

Referring to FIG. 7, the display panel 100 includes a base part SUB, a display layer DPL located on the base part SUB, and an encapsulation layer TFE located on the display layer DPL.

The display layer DPL may be located on an upper surface of the base part SUB. The display layer DPL may include a circuit layer CCL, a light emitting element layer EML, a wavelength conversion layer WLCL, and a color filter layer CFL.

The circuit layer CCL may be located on the upper surface of the base part SUB. The circuit layer CCL may include at least one transistor driving a plurality of pixels to drive the light emitting element layer EML.

The circuit layer CCL may include a buffer layer BF, a transistor TR, a gate insulating film GI, an interlayer insulating film ILD, a first passivation layer PAS1, and a first planarization layer OC1.

The buffer layer BF may be located on the base part SUB. The buffer layer BF may include an inorganic material capable of reducing or preventing permeation of air or moisture. For example, the buffer layer BF may include a plurality of inorganic films that are alternately stacked.

The transistor TR may be located on the buffer layer BF, and may constitute a pixel circuit of each of the plurality of pixels. For example, the transistor TR may be a driving transistor or a switching transistor of a pixel circuit. The transistor TR may include a semiconductor pattern ACT, a gate electrode GE, a source electrode SE, and a drain electrode DE.

The semiconductor pattern ACT may be located on the buffer layer BF. The semiconductor pattern ACT may overlap the gate electrode GE while beneath the gate electrode GE in the third direction DR3 (or the thickness direction of the display device 10), and may be insulated from the gate electrode GE by the gate insulating film GI.

The gate insulating film GI may be located on the semiconductor pattern ACT. For example, the gate insulating film GI may cover the semiconductor pattern ACT and the buffer layer BF exposed by the semiconductor pattern ACT, and may insulate the semiconductor pattern ACT and the gate electrode GE from each other. The gate insulating film GI may include contact holes through which the source electrode SE and the drain electrode DE penetrate, respectively.

The gate electrode GE may be located on the gate insulating film GI. The gate electrode GE may be located to overlap the semiconductor pattern ACT, which is located thereunder, in the third direction DR3.

The interlayer insulating film ILD may be located on the gate electrode GE. For example, the interlayer insulating film ILD may include contact holes through which the source electrode SE and the drain electrode DE penetrate, respectively. The contact holes of the interlayer insulating film ILD may overlap, and may be connected to, the contact holes of the gate insulating film GI in the third direction DR3.

The source electrode SE and the drain electrode DE may be located to be spaced apart from each other on the interlayer insulating film ILD. In one or more embodiments, the drain electrode DE may be connected to a data line or to a driving voltage line. The drain electrode DE may be electrically connected to the semiconductor pattern ACT through the contact hole penetrating through the gate insulating film GI and the interlayer insulating film ILD. The source electrode SE may be electrically connected to a first electrode AE of the light emitting element layer EML. The source electrode SE may be connected to the semiconductor pattern ACT through the contact hole penetrating through the gate insulating film GI and the interlayer insulating film ILD.

The first passivation layer PAS1 may be located on the source electrode SE and the drain electrode DE. The first passivation layer PAS1 may be located above the transistor TR to protect the transistor TR. The first passivation layer PAS1 may include a contact hole through which the first electrode AE of the light emitting element layer EML penetrates.

The first planarization layer OC1 may be located on the first passivation layer PAS1. The first planarization layer OC1 may be located on the first passivation layer PAS1 to planarize a step generated by a plurality of layers located thereunder. The first planarization layer OC1 may include a contact hole through which the first electrode AE of the light emitting element layer EML penetrates. The first planarization layer OC1 may include an organic material.

The light emitting element layer EML may be located on the circuit layer CCL. The light emitting element layer EML may include a plurality of light emitting elements ED, and the plurality of light emitting elements ED may emit light according to an electrical signal transmitted from the circuit layer CCL. The light emitted from the light emitting element ED may be incident on the wavelength conversion layer WLCL located on the light emitting element layer EML.

The light emitting element layer EML may include the light emitting element ED, the first electrode AE, a second electrode CE, first banks BNK1, a second bank BNK2, a second passivation layer PAS2, and a second planarization layer OC2.

The second bank BNK2 may be located on the first planarization layer OC1 of the circuit layer CCL, and may be located along a boundary of each pixel PX. The second bank BNK2 may be located in the light blocking areas BA. The second bank BNK2 may include openings exposing the first banks BNK1 and the plurality of light emitting elements ED. The first to third light emission areas LA1, LA2, and LA3 and the light blocking areas BA may be divided by the second bank BNK2 and corresponding to the openings of the second bank BNK2. That is, the second bank BNK2 may define the light emission areas LA and the light blocking areas BA of the display device 10.

The first banks BNK1 and the plurality of light emitting elements ED may be located in the openings partitioned by the second bank BNK2.

The first banks BNK1 may be located on the first planarization layer OC1. The number of first banks BNK1 may be plural, and the plurality of first banks BNK1 may be located in the openings partitioned by the second bank BNK2, and may be located to be spaced apart from each other. The first banks BNK1 may be located to respectively overlap the first to third light emission areas LA1, LA2, and LA3 defined by the second bank BNK2.

The first electrode AE may be located on the first planarization layer OC1. The first electrode AE may be located on the first bank BNK1 to cover the first bank BNK1. The first electrode AE may be electrically connected to the source electrode SE of the transistor TR through the contact hole passing through the first planarization layer OC1 and the first passivation layer PAS1. The first electrode AE may be connected to the source electrode SE of the transistor TR to receive a driving current.

The second electrode CE may be located on the first planarization layer OC1. The second electrode CE may be located on the first bank BNK1 to cover the first bank BNK1. The second electrode CE may receive a common voltage supplied to all pixels.

A first insulating layer IL1 may be located on the first electrode AE and the second electrode CE. The first insulating layer IL1 may be located between the first electrode AE and the second electrode CE to electrically insulate the first electrode AE and the second electrode CE from each other.

The light emitting element ED may be located on the first insulating layer IL1 so that both ends thereof are put on the first electrode AE and the second electrode CE, respectively. One end of the light emitting element ED may be electrically connected to the first electrode AE, and the other end of the light emitting element ED may be electrically connected to the second electrode CE.

The plurality of light emitting elements ED may include active layers having the same material to emit light of the same wavelength band or light of the same color. Light emitted from each of the first to third light emission areas LA1, LA2, and LA3 may have the same color. For example, the plurality of light emitting elements ED may emit light of a third color or blue light having a peak wavelength in the range of about 440 nm to about 480 nm. Therefore, the light emitting element layer EML may emit the light of the third color or the blue light.

The second passivation layer PAS2 may be located on the second bank BNK2. The second passivation layer PAS2 may be located on the plurality of light emitting elements ED to protect the plurality of light emitting elements ED. The second passivation layer PAS2 may reduce or prevent permeation of impurities such as moisture or air from the outside to reduce or prevent damage to the plurality of light emitting elements ED.

The second planarization layer OC2 may be located on the second passivation layer PAS2. The second planarization layer OC2 may serve to planarize a step generated by a plurality of members located thereunder. For example, the second planarization layer OC2 may include an organic material.

The wavelength conversion layer WLCL may be located on the light emitting element layer EML. The wavelength conversion layer WLCL may serve to convert a wavelength of light emitted from the light emitting element layer EML and incident to the wavelength conversion layer WLCL so as to correspond to a color corresponding to each pixel PX, or may serve to transmit the light therethrough.

The wavelength conversion layer WLCL may be located on the second planarization layer OC2. The wavelength conversion layer WLCL may include a first capping layer CAP1, a first light blocking member BK1, a first wavelength conversion pattern WLC1, a second wavelength conversion pattern WLC2, a light transmission pattern LTU, a second capping layer CAP2, and a third planarization layer OC3.

The first capping layer CAP1 may be located on the second planarization layer OC2 of the light emitting element layer EML. The first capping layer CAP1 may seal lower surfaces of the first and second wavelength conversion patterns WLC1 and WLC2 and the light transmission pattern LTU. For example, the first capping layer CAP1 may include an inorganic material.

The first light blocking member BK1 may be located in the light blocking areas BA on the first capping layer CAP1. The first light blocking member BK1 may overlap the second bank BNK2 in the thickness direction. The first light blocking member BK1 may block transmission of light. The first light blocking member BK1 may reduce or prevent light permeating between the first to third light emission areas LA1, LA2, and LA3 and mixing colors with each other to improve a color reproduction rate of the display device 10. The first light blocking member BK1 may be located in a lattice shape surrounding the first to third light emission areas LA1, LA2, and LA3 in plan view.

The first light blocking member BK1 may include an organic light blocking material and a liquid repellent component. For example, the first light blocking member BK1 may be made of a black organic material including a liquid repellent component. The first light blocking member BK1 may be formed through coating and exposing processes or the like of an organic light blocking material including a liquid repellent component.

The first wavelength conversion pattern WLC1 may be located in the first light emission area LA1 on the first capping layer CAP1. The first wavelength conversion pattern WLC1 may be surrounded by the first light blocking member BK1. The first wavelength conversion pattern WLC1 may include a first base resin BS1, first scatterers SCT1, and first wavelength conversion materials WLS1.

The first base resin BS1 may include a material having a relatively high light transmittance. The first base resin BS1 may be made of a transparent organic material. For example, the first base resin BS1 may include at least one of organic materials such as an epoxy-based resin, an acrylic resin, a cardo-based resin, and an imide-based resin.

The first scatterer SCT1 may have a refractive index that is different from that of the first base resin BS1, and may form an optical interface with the first base resin BS1. For example, the first scatterer SCT1 may include a light scattering material or a light scattering particle for scattering at least a portion of transmitted light. For example, the first scatterer SCT1 may include a metal oxide such as titanium oxide (TiO₂), zirconium oxide (ZrO₂), aluminum oxide (Al₂O₃), indium oxide (In₂O₃), zinc oxide (ZnO), or tin oxide (SnO₂) or include an organic particle such as an acrylic resin or a urethane-based resin. The first scatterer SCT1 may scatter light in a random direction regardless of an incident direction of incident light without substantially converting a peak wavelength of the incident light.

The first wavelength conversion material WLS1 may convert or shift the peak wavelength of the incident light to a first peak wavelength. For example, the first wavelength conversion material WLS1 may convert the blue light provided from the display device 10 into red light having a single peak wavelength in the range of about 610 nm to about 650 nm and may emit the red light. The first wavelength conversion material WLS1 may be a quantum dot, a quantum rod, or a phosphor. The quantum dot may be a particulate matter for emitting a corresponding color while electrons are transitioning from a conduction band to a valence band.

A portion of the blue light provided from the light emitting element layer EML may be transmitted through the first wavelength conversion material WLS1 without being converted into red light by the first wavelength conversion material WLS1. Light incident on a first color filter CF1, which will be described later, without being converted by the first wavelength conversion material WLS1 of the blue light provided from the light emitting element layer EML may be blocked by the first color filter CF1. In addition, the red light converted by the first wavelength conversion pattern WLC1 in the blue light provided from the light emitting element layer EML may be transmitted through the first color filter CF1 and then emitted to the outside. Accordingly, the first light emission area LA1 may emit the red light.

The second wavelength conversion pattern WLC2 may be located in the second light emission area LA2 on the first capping layer CAP1. The second wavelength conversion pattern WLC2 may be surrounded by the first light blocking member BK1. The second wavelength conversion pattern WLC2 may include a second base resin BS2, second scatterers SCT2, and second wavelength conversion materials WLS2.

The second base resin BS2 may include a material having a relatively high light transmittance. The second base resin BS2 may be made of a transparent organic material. For example, the second base resin BS2 may be made of the same material as the first base resin BS1, or may be made of the material exemplified in the first base resin BS1.

The second scatterer SCT2 may have a refractive index that is different from that of the second base resin BS2, and may form an optical interface with the second base resin BS2. For example, the second scatterer SCT2 may include a light scattering material or a light scattering particle for scattering at least a portion of transmitted light. For example, the second scatterer SCT2 may be made of the same material as the first scatterer SCT1 or may be made of the material exemplified in the first scatterer SCT1. The second scatterer SCT2 may scatter light in a random direction regardless of an incident direction of incident light without substantially converting a peak wavelength of the incident light.

The second wavelength conversion material WLS2 may convert or shift the peak wavelength of the incident light to a second peak wavelength that is different from the first peak wavelength of the first wavelength conversion material WLS1. For example, the second wavelength conversion material WLS2 may convert the blue light provided from the display device 10 into green light having a single peak wavelength in the range of about 510 nm to about 550 nm and emit the green light. The second wavelength conversion material WLS2 may be a quantum dot, a quantum rod, or a phosphor. The second wavelength conversion material WLS2 may be formed of the quantum dot, the quantum rod, or the phosphor so that a wavelength conversion range of the second wavelength conversion material WLS2 is different from the wavelength conversion range of the first wavelength conversion material WLS1.

The light transmission pattern LTU may be located in the third light emission area LA3 on the first capping layer CAP1. The light transmission pattern LTU may be surrounded by the first light blocking member BK1. The light transmission pattern LTU may transmit incident light therethrough while maintaining a peak wavelength of the incident light. The light transmission pattern LTU may include a third base resin BS3 and third scatterers SCT3.

The third base resin BS3 may include a material having a relatively high light transmittance. The third base resin BS3 may be made of a transparent organic material. For example, the third base resin BS3 may be made of the same material as the first or second base resin BS1 or BS2, or may be made of the material exemplified in the first or second base resin BS1 or BS2.

The third scatterer SCT3 may have a refractive index that is different from that of the third base resin BS3, and may form an optical interface with the third base resin BS3. For example, the third scatterer SCT3 may include a light scattering material or a light scattering particle for scattering at least a portion of transmitted light. For example, the third scatterer SCT3 may be made of the same material as the first or second scatterer SCT1 or SCT2, or may be made of the material exemplified in the first or second scatterer SCT1 or SCT2. The third scatterer SCT3 may scatter light in a random direction regardless of an incident direction of incident light without substantially converting a peak wavelength of the incident light.

Because the wavelength conversion layer WLCL is directly located on the second planarization layer OC2 of the light emitting element layer EML, the display device 10 may not require a separate substrate or a base part for the first and second wavelength conversion patterns WLC1 and WLC2 and the light transmission pattern LTU. Accordingly, the first and second wavelength conversion patterns WLC1 and WLC2 and the light transmission pattern LTU may be easily aligned with the first to third light emission areas LA1, LA2, and LA3, respectively, and a thickness of the display device 10 may be relatively reduced.

The second capping layer CAP2 may cover the first and second wavelength conversion patterns WLC1 and WLC2, the light transmission pattern LTU, and the first light blocking member BK1. For example, the second capping layer CAP2 may seal the first and second wavelength conversion patterns WLC1 and WLC2 and the light transmission pattern LTU to reduce or prevent damage to, or contamination of, the first and second wavelength conversion patterns WLC1 and WLC2 and the light transmission pattern LTU. For example, the second capping layer CAP2 may include an inorganic material.

The third planarization layer OC3 may be located on the second capping layer CAP2 to planarize upper ends of the first and second wavelength conversion patterns WLC1 and WLC2 and the light transmission pattern LTU. For example, the third planarization layer OC3 may include an organic material.

The color filter layer CFL may be located on the wavelength conversion layer WLCL. The color filter layer CFL may serve to block emission of light of a color other than the color corresponding to each pixel PX.

The color filter layer CFL may be located on the third planarization layer OC3 of the wavelength conversion layer WLCL. The color filter layer CFL may include a second light blocking member BK2, first to third color filters CF1, CF2, and CF3, and a third passivation layer PAS3.

The second light blocking member BK2 may be located in the light blocking areas BA on the third planarization layer OC3. The second light blocking member BK2 may overlap the first light blocking member BK1 and/or the second bank BNK2 in the thickness direction. The second light blocking member BK2 may block transmission of light. The second light blocking member BK2 may reduce or prevent permeation of the light between the first to third light emission areas LA1, LA2, and LA3 and mixing colors with each other to improve a color reproduction rate of the display device 10. The second light blocking member BK2 may be located in a lattice shape surrounding the first to third light emission areas LA1, LA2, and LA3 in plan view.

The first color filter CF1 may be located in the first light emission area LA1 on the third planarization layer OC3. The first color filter CF1 may be surrounded by the second light blocking member BK2. The first color filter CF1 may overlap the first wavelength conversion pattern WLC1 in the thickness direction. The first color filter CF1 may selectively transmit the light of the first color (e.g., red light) and may block or absorb the light of the second color (e.g., green light) and the light of the third color (e.g., blue light). For example, the first color filter CF1 may be a red color filter and may include a red colorant.

The second color filter CF2 may be located in the second light emission area LA2 on the third planarization layer OC3. The second color filter CF2 may be surrounded by the second light blocking member BK2. The second color filter CF2 may overlap the second wavelength conversion pattern WLC2 in the thickness direction. The second color filter CF2 may selectively transmit the light of the second color (e.g., the green light), and may block or absorb the light of the first color (e.g., the red light) and the light of the third color (e.g., the blue light). For example, the second color filter CF2 may be a green color filter and may include a green colorant.

The third color filter CF3 may be located in the third light emission area LA3 on the third planarization layer OC3. The third color filter CF3 may be surrounded by the second light blocking member BK2. The third color filter CF3 may overlap the light transmission pattern LTU in the thickness direction. The third color filter CF3 may selectively transmit the light of the third color (e.g., the blue light), and may block or absorb the light of the first color (e.g., the red light) and the light of the second color (e.g., the green light). For example, the third color filter CF3 may be a blue color filter and may include a blue colorant.

The first to third color filters CF1, CF2, and CF3 may absorb a portion of light introduced from the outside of the display device 10 to reduce reflected light due to external light. Therefore, the first to third color filters CF1, CF2, and CF3 may reduce or prevent distortion of colors due to external light reflection.

Because the first to third color filters CF1, CF2, and CF3 are directly located on the third planarization layer OC3 of the wavelength conversion layer WLCL, the display device 10 may not require a separate substrate or a base part for the first to third color filters CF1, CF2, and CF3. Accordingly, a thickness of the display device 10 may be relatively reduced.

The third passivation layer PAS3 may cover the first to third color filters CF1, CF2, and CF3. The third passivation layer PAS3 may protect the first to third color filters CF1, CF2, and CF3.

The encapsulation layer TFE may be located on the third passivation layer PAS3 of the color filter layer CFL. The encapsulation layer TFE may cover the upper surface and the side surfaces of the display layer DPL. For example, the encapsulation layer TFE may include at least one inorganic film to reduce or prevent permeation of oxygen or moisture. In addition, the encapsulation layer TFE may include at least one organic film to protect the display device 10 from foreign matters such as dust.

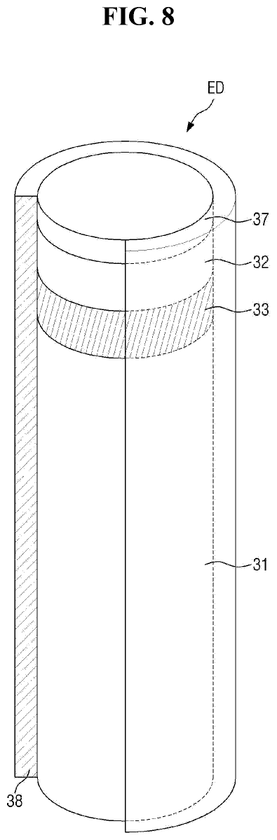

FIG. 8 is a schematic perspective view of a light emitting element according to one or more embodiments.

Referring to FIG. 8, the light emitting element ED is a particle type element, and may have a rod or cylindrical shape having an aspect ratio (e.g., a predetermined aspect ratio). A length of the light emitting element ED may be greater than a diameter of the light emitting element ED, and the aspect ratio of the light emitting element ED may be about 1.2:1 to about 100:1, but the present disclosure is not limited thereto.

The light emitting element ED may have a size of a nanometer scale (e.g., about 1 nm or more and less than about 1 μm) to a micrometer scale (e.g., about 1 μm or more and less than about 1 mm). In one or more embodiments, the light emitting element ED may have a size of a nanometer scale or have a size of a micrometer scale, in both the length and the diameter. In some other embodiments, the diameter of the light emitting element ED may have a size of a nanometer scale, while the length of the light emitting element ED may have a size of a micrometer scale. In some embodiments, some of the light emitting elements ED have sizes of a nanometer scale in diameter and/or length, while the others of the light emitting elements ED may have a size of a micrometer scale in diameter and/or length.

The light emitting element ED may include an inorganic light emitting diode. The inorganic light emitting diode may include a plurality of semiconductor layers. For example, the inorganic light emitting diode may include a first conductivity-type (e.g., n-type) semiconductor layer, a second conductivity-type (e.g., p-type) semiconductor layer, and an active semiconductor layer interposed between the first conductivity-type semiconductor layer and the second conductivity-type semiconductor layer. The active semiconductor layer may receive holes and electrons provided from the first conductivity-type semiconductor layer and the second conductivity-type semiconductor layer, respectively, and the holes and the electrons reaching the active semiconductor layer may be combined with each other to emit light.

In one or more embodiments, the above-described semiconductor layers may be sequentially stacked along a length direction of the light emitting element ED. The light emitting element ED may include a first semiconductor layer 31, an element active layer 33, and a second semiconductor layer 32 that are sequentially stacked in the length direction, as illustrated in FIG. 8. The first semiconductor layer 31, the element active layer 33, and the second semiconductor layer 32 may be the above-described first conductivity-type semiconductor layer, active semiconductor layer, and second conductivity-type semiconductor layer, respectively.

The first semiconductor layer 31 may be doped with a first conductivity-type dopant. The first conductivity-type dopant may be Si, Ge, Sn, or the like. In one or more embodiments, the first semiconductor layer 31 may be made of n-GaN doped with n-type Si.

The second semiconductor layer 32 may be located to be spaced apart from the first semiconductor layer 31 with the element active layer 33 interposed therebetween. The second semiconductor layer 32 may be doped with a second conductivity-type dopant such as Mg, Zn, Ca, Se, or Ba. In one or more embodiments, the second semiconductor layer 32 may be made of p-GaN doped with p-type Mg.

The element active layer 33 may include a material having a single or multiple quantum well structure. As described above, the element active layer 33 may emit light by a combination of electron-hole pairs according to an electrical signal applied through the first semiconductor layer 31 and the second semiconductor layer 32.

In some embodiments, the element active layer 33 may have a structure in which semiconductor materials having large band gap energy and semiconductor materials having small band gap energy are alternately stacked, and may include other Group III to Group V semiconductor materials depending on a wavelength band of emitted light.

The light emitted from the element active layer 33 may be emitted not only to outer surfaces of the light emitting element ED in the length direction, but also to both sides of the light emitting element ED. That is, an emission direction of the light from the element active layer 33 is not limited to one direction.

The light emitting element ED may further include an element electrode layer 37 located on the second semiconductor layer 32. The element electrode layer 37 may be in contact with the second semiconductor layer 32. The element electrode layer 37 may be an ohmic contact electrode, but is not limited thereto, and may also be a Schottky contact electrode.

The element electrode layer 37 may be located between the second semiconductor layer 32 and a contact electrode to be connected thereto to reduce resistance, when both ends of the light emitting element ED and the contact electrodes 710 and 720 are electrically connected to each other to apply an electrical signal to the first semiconductor layer 31 and the second semiconductor layer 32. The element electrode layer 37 may include at least one of aluminum (Al), titanium (Ti), indium (In), gold (Au), silver (Ag), indium tin oxide (ITO), indium zinc oxide (IZO), and indium tin zinc oxide (ITZO). The element electrode layer 37 may also include an n-type or p-type doped semiconductor material.

The light emitting element ED may further include an element insulating film 38 surrounding outer peripheral surfaces of the first semiconductor layer 31, the second semiconductor layer 32, the element active layer 33, and/or the element electrode layer 37. The element insulating film 38 may be located to surround at least an outer surface of the element active layer 33, and may extend in one direction in which the light emitting element ED extends. The element insulating film 38 may serve to protect the first semiconductor layer 31, the second semiconductor layer 32, the element active layer 33, and the element electrode layer 37. The element insulating film 38 may be made of materials having insulating properties to reduce or prevent the likelihood of an electrical short-circuit that may occur when the element active layer 33 is in direct contact with an electrode through which an electrical signal is transferred to the light emitting element ED. In addition, the element insulating film 38 protects the outer peripheral surfaces of the first and second semiconductor layers 31 and 32 as well as the element active layer 33, and may thus reduce or prevent a decrease in luminous efficiency.

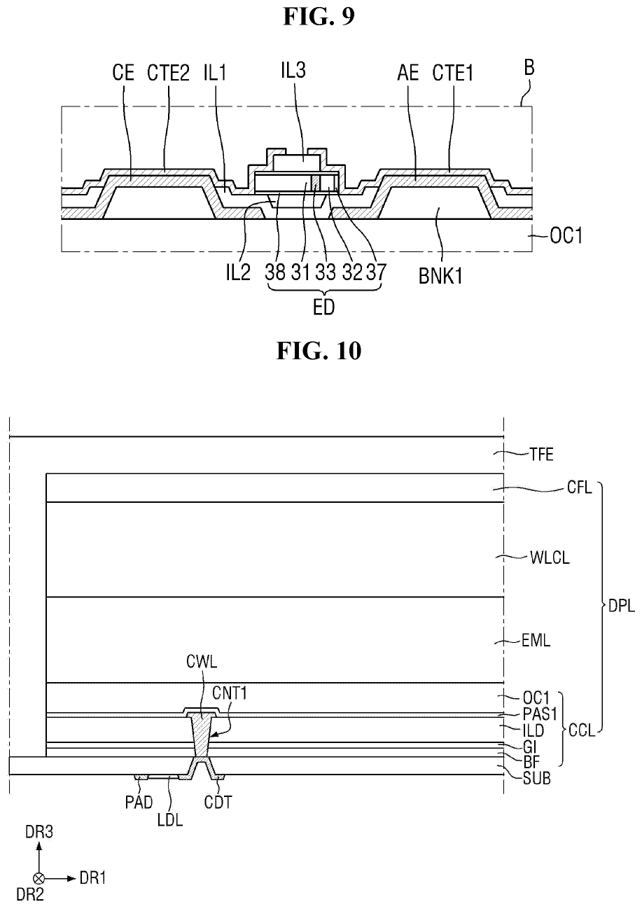

FIG. 9 is an enlarged view of area B of FIG. 7.

Hereinafter, a cross-sectional structure of the light emitting element layer EML will be described with reference to FIGS. 7 to 9. The light emitting element layer EML may be located on the first planarization layer OC1 of the circuit layer CCL.

The light emitting element layer EML according to one or more embodiments may include the first banks BNK1, the second bank BNK2, the light emitting element ED, the first electrode AE, the second electrode CE, a first contact electrode CTE1, a second contact electrode CTE2, first to third insulating layers IL1, IL2, and IL3, the second passivation layer PAS2, and the second planarization layer OC2.

The plurality of first banks BNK1 may be located in each of the first to third light emission areas LA1, LA2, and LA3. The plurality of first banks BNK1 may be located on the first planarization layer OC1, and side surfaces of each of the plurality of first banks BNK1 may be inclined from the first planarization layer OC1. The first bank BNK1 may include polyimide PI, but is not limited thereto.

The first and second electrodes AE and CE may be located on respective corresponding first banks BNK1. The first and second electrodes AE and CE may be electrically connected to the light emitting elements ED, respectively, and a voltage (e.g., a predetermined voltage) may be applied to the first and second electrodes AE and CE so that the light emitting elements ED emit light. For example, the first and second electrodes AE and CE may be electrically connected to the light emitting element ED located between the first banks BNK1 through first and second contact electrodes CTE1 and CTE2, respectively, and may transfer electrical signals applied to the first and second electrodes AE and CE to the light emitting element ED through the first and second contact electrodes CTE1 and CTE2.

Each of the first and second electrodes AE and CE may include a conductive material having a high reflectivity. For example, each of the first and second electrodes AE and CE may include a metal such as silver (Ag), copper (Cu), aluminum (Al), molybdenum (Mo), or titanium (Ti), or may include an alloy including aluminum (Al), nickel (Ni), lanthanum (La), or the like, having a high reflectivity. The first and second electrodes AE and CE may reflect light incident from the light emitting element ED in an upward direction of the display device 10. In some embodiments, each of the first and second electrodes AE and CE may further include a transparent conductive material. For example, each of the first and second electrodes AE and CE may further include at least one of indium tin oxide (ITO), indium zinc oxide (IZO), and indium tin zinc oxide (ITZO). In some other embodiments, the first and second electrodes AE and CE may have a structure in which one or more layers made of the transparent conductive material and one or more layers made of the metal having the high reflectivity are stacked, or may be formed as one layer including the transparent conductive material and the metal having the high reflectivity. For example, each of the first and second electrodes AE and CE may have a stacked structure such as ITO/Ag/ITO/, ITO/Ag/IZO, or ITO/Ag/ITZO/IZO.

The first insulating layer IL1 may be located on the first planarization layer OC1, the first electrode AE, and the second electrode CE. The first insulating layer IL1 may cover a portion of each of the first and second electrodes AE and CE. For example, the first insulating layer IL1 may include an opening exposing portions of the first and second electrodes AE and CE corresponding to upper surfaces of the first banks BNK1. The first insulating layer IL1 may protect the first and second electrodes AE and CE, and insulate the first and second electrodes AE and CE from each other. The first insulating layer IL1 may reduce or prevent the likelihood of the light emitting element ED being in direct contact with, and being damaged by, other members.

For example, the first insulating layer IL1 may include an inorganic insulating material, and may include a recessed step between the first and second electrodes AE and CE. The second insulating layer IL2 may fill the recessed step of the first insulating layer IL1. Accordingly, the second insulating layer IL2 may planarize an upper surface of the first insulating layer IL1, and the light emitting element ED may be located on the first and second insulating layers IL1 and IL2 so that both ends thereof are put on the first electrode AE and the second electrode CE, respectively.

The light emitting element ED may be located between the first banks BNK1 so that both ends thereof are put on the first and second insulating layers IL1 and IL2, respectively, on the first electrode AE and the second electrode CE. The light emitting element ED may be electrically connected to the first electrode AE through the first contact electrode CTE1, and may be electrically connected to the second electrode CE through the second contact electrode CTE2.

As described above, the light emitting element ED may include the semiconductor layers 31 and 32 doped with different conductivity-types. The light emitting element ED may include the plurality of semiconductor layers 31 and 32, and may be oriented so that one end thereof is directed toward a corresponding direction according to directions of electric fields generated on the first and second electrodes AE and CE. For example, the light emitting element ED may have a shape in which it extends in one direction, and respective ends of the light emitting element ED in an extension direction may be located on the first electrode AE and the second electrode CE.

The light emitting element ED may be located so that the direction in which the light emitting element ED extends is substantially parallel to the base part SUB, and the plurality of semiconductor layers included in the light emitting element ED may be sequentially located along a direction that is substantially parallel to an upper surface of the base part SUB. For example, in the light emitting element ED, in a cross section crossing both ends of the light emitting element ED, the first semiconductor layer 31, the element active layer 33, the second semiconductor layer 32, and the element electrode layer 37 may be sequentially formed in a direction substantially horizontal with respect to one surface of the base part SUB. The light emitting element ED may be aligned so that one end of the light emitting element ED at which the second semiconductor layer 32 is positioned is put on the first electrode AE, and so that the other end of the light emitting element ED at which the first semiconductor layer 31 is positioned is put on the second electrode CE. However, the present disclosure is not limited thereto, and in some other light emitting elements ED, one end of the light emitting element ED at which the second semiconductor layer 32 is positioned may be put on the second electrode CE, and the other end of the light emitting element ED at which the first semiconductor layer 31 is positioned may be put on the first electrode AE.

The third insulating layer IL3 may be partially located on the light emitting element ED. The third insulating layer IL3 may be located to partially cover an outer surface of the light emitting element ED, but may be located so as not to cover both ends of the light emitting element ED. The third insulating layer IL3 may serve to protect the light emitting element ED, and to fix the light emitting element ED in a process of manufacturing the display device 10.

The first contact electrode CTE1 may be located on the first electrode AE. The first contact electrode CTE1 may be in contact with each of the first electrode AE and one end of the light emitting element ED. The first contact electrode CTE1 may electrically connect the light emitting element ED and the first electrode AE to each other.

The second contact electrode CTE2 may be located on the second electrode CE. The second contact electrode CTE2 may be in contact with each of the second electrode CE and the other end of the light emitting element ED. The second contact electrode CTE2 may electrically connect the light emitting element ED and the second electrode CE to each other.

For example, one end of the light emitting element ED at which the second semiconductor layer 32 is positioned may be electrically connected to the first electrode AE through the first contact electrode CTE1, and the other end of the light emitting element ED at which the first semiconductor layer 31 is positioned may be electrically connected to the second electrode CE through the second contact electrode CTE2. That is, respective ends of the light emitting element ED are in contact with the first and second contact electrodes CTE1 and CTE2 such that the light emitting element ED may receive electrical signals applied from the first and second electrodes AE and CE, and the light may be emitted from the element active layer 33 of the light emitting element ED according to the electrical signals.

Each of the first and second contact electrodes CTE1 and CTE2 may include a conductive material. For example, the first and second contact electrodes CTE1 and CTE2 may include ITO, IZO, ITZO, aluminum (Al), or the like. As an example, each of the first and second contact electrodes CTE1 and CTE2 may include a transparent conductive material, and the light emitted from the light emitting element ED may be transmitted through the first and second contact electrodes CTE1 and CTE2 and then may travel toward the first and second electrodes AE and CE, and also may be reflected by outer surfaces of the first and second electrodes AE and CE.

FIG. 10 is a schematic cross-sectional view illustrating a relative layout of the display panel, a pad part, a connection line, and a conductive part at an edge of the display panel according to one or more embodiments.

Referring to FIG. 10, the circuit layer CCL may further include a connection line CWL. The connection line CWL may be exposed on a lower surface of the display layer DPL. The connection line CWL may be located on the interlayer insulating film ILD, and may be formed of the same material as the source electrode SE or the drain electrode DE on the same layer as the source electrode SE or the drain electrode DE, but the present disclosure is not limited thereto. As an example, the connection line CWL may be electrically connected to a data line to supply a data voltage to the transistor. As another example, the connection line CWL may be electrically connected to a power line to supply a source voltage. As still another example, the connection line CWL may be connected to a plurality of scan lines to be electrically connected to a gate line of the transistor TR.

In one or more embodiments, the connection line CWL may be inserted into a first contact hole CNT1 that penetrates through the interlayer insulating film ILD, the gate insulating film GI, and the buffer layer BF to be electrically connected to the conductive part CDT located on the lower surface of the base part SUB and in the opening of the base part SUB. For example, the connection line CWL may be in direct contact with the conductive part CDT.

The connection line CWL exposed on the lower surface of the display layer DPL may be electrically connected to the conductive part CDT through the opening penetrating through the base part SUB. The opening passing through the base part SUB may overlap the first contact hole CNT1 in the third direction DR3. The connection line CWL may supply an electrical signal received from the pad part PAD to the circuit layer CCL through the conductive part CDT and the lead line LDL.

The pad part PAD may be located on a lower surface of the base part SUB. The pad part PAD may be electrically connected to the conductive part CDT through the lead line LDL, as described above. The pad part PAD may receive various voltages or signals from the flexible film, and may supply the received voltages or signals to the connection line CWL. The lead line LDL may be located between the conductive part CDT and the pad part PAD to electrically connect the conductive part CDT and the pad part PAD to each other.

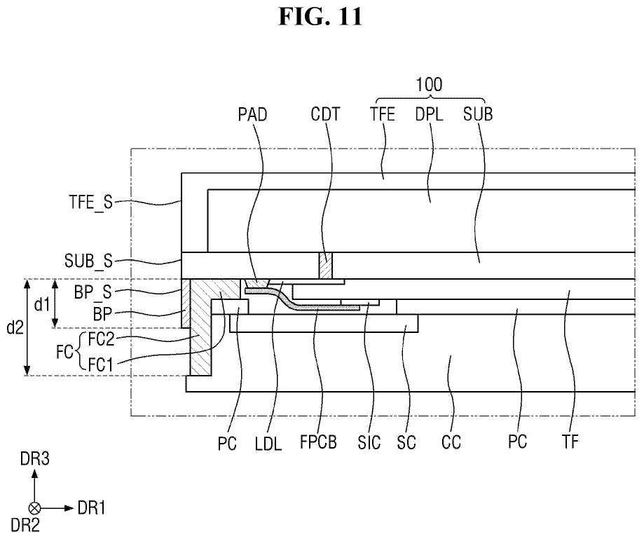

FIG. 11 is an enlarged cross-sectional view illustrating an example of area A of FIG. 4.

Referring to FIG. 11, the buffer part BP may be located on an outer side surface of the sidewall part FC2. The buffer part BP may be located on the outer side surface of the sidewall part FC2, but may expose a portion of the outer surface of the sidewall part FC2. The buffer part BP may cover an upper end of the sidewall part FC2 on the outer side surface of the sidewall part FC2, but also may expose a lower end of the sidewall part FC2. That is, a first length d1 of the buffer part BP in the third direction DR3 may be smaller than a second length d2 of the sidewall part FC2 of the lower frame FC in the third direction DR3.

Because the first length d1 of the buffer part BP is smaller than the second length d2 of the sidewall part FC2, energy or effort for cutting the buffer part BP in a cutting process of substantially simultaneously or concurrently cutting the base part SUB and the buffer part BP, among processes of manufacturing a display device 10 to be described later, is reduced or minimized, such that manufacturing process efficiency of the display device 10 may be improved.

A side surface BP_S of the buffer part BP may be aligned with a side surface of the display panel 100. The side surface of the display panel 100 may be constituted by a side surface SUB_S of the base part SUB or a side surface TFE_S of the encapsulation layer TFE. In one or more embodiments, the side surface of the display panel 100 may be constituted by the side surface SUB_S of the base part SUB and the side surface TFE_S of the encapsulation layer TFE. However, the present disclosure is not limited thereto, and the side surface of the display panel 100 may also be constituted by only the side surface TFE_S of the encapsulation layer TFE.

The side surface BP_S of the buffer part BP may be aligned with the side surface SUB_S of the base part SUB and the side surface TFE_S of the encapsulation layer TFE. The side surface BP_S of the buffer part BP, the side surface SUB_S of the base part SUB, and the side surface TFE_S of the encapsulation layer TFE aligned with each other may be substantially simultaneously or concurrently cut to be formed through the same cutting process. A detailed description therefor will be provided later.

A side surface of the sidewall part FC2 of the lower frame FC may be arranged inside (e.g., with respect to plan view) the side surface SUB_S of the base part SUB and the side surface TFE_S of the encapsulation layer TFE. The bottom chassis CC may be located at the lowermost portion of the display device 10. An outer side surface of the bottom chassis CC, or a portion thereof, may be arranged inside (with respect to plan view) the side surface BP_S of the buffer part BP and the side surface of the display panel 100.

In the present embodiments, the buffer part BP of the plurality of lower members located under the display panel 100 may be formed to be aligned with the side surface of the display panel 100 and the other lower members, except for the buffer part BP that may be formed to be positioned inside the side surface of the display panel 100 to reduce or prevent visibility of the lower members of the display panel 100 in an area outside the display panel 100.

In addition, the buffer part BP constitutes a side surface of the display device 10 together with the display panel 100 at the edge of the display panel 100, such that an impact applied from the outside of the display device 10 to a side portion of the display device 10 may be dispersed so as not to be concentrated on the edge of the display panel 100. Accordingly, damage to the display panel 100 due to the impact generated from the outside of the display device 10 may be reduced or prevented.

In addition, the buffer part BP is located to completely cover the lower surface of the base part SUB at an edge of the base part SUB, such that an area in which the edge portion of the base part SUB is exposed to the outside is reduced or minimized, and thus, heat dissipation of the display device 10 may be improved.

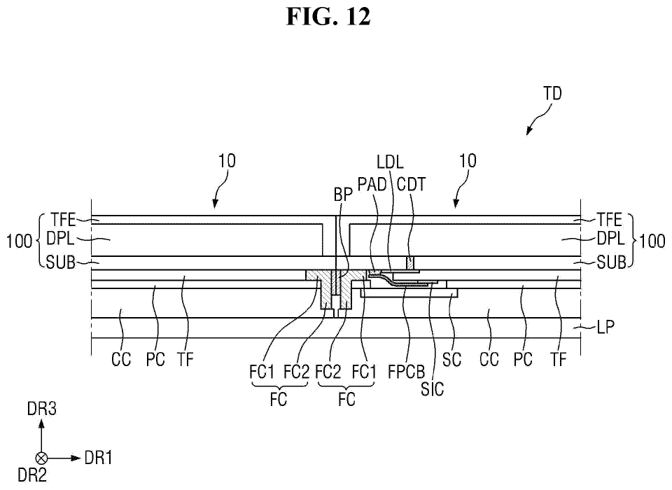

FIG. 12 is a schematic cross-sectional view illustrating display devices located adjacent to each other in the tiled display device according to one or more embodiments.

Referring to FIGS. 4 and 12, the plurality of display devices 10 may be located on the lower plate LP. The bottom chassis CC of the display devices 10 may be fixed by a separate fastening member, or may be aligned by a moving member, on the lower plate LP. Meanwhile, to reduce or minimize visual recognition of the boundary areas SM between the display areas DA of the display devices 10 by the user, it is suitable to reduce or minimize intervals between the display devices 10 located adjacent to each other. Accordingly, the side surfaces of the display devices 10 located adjacent to each other may be aligned to be in contact with, and to abut on, each other.

For example, the side surfaces of the display panels 100 and the side surfaces of the buffer parts BP constituting the side surfaces of the display devices 10 located adjacent to each other may be in contact with, and may abut on, each other. For example, in FIG. 12, a right side surface of the base part SUB of a display device 10 located on the left side, and a left side surface of the base part SUB of another display device 10 located on the right side, may be in contact with, and may abut on, each other. In addition, a right side surface of the buffer part BP of the display device 10 that is located on the left side, and a left side surface of the buffer part BP of the display device 10 that is located on the right side, may be in contact with, and may abut on, each other.

Meanwhile, the members located under the display panels 100, with the exception of the buffer parts BP, may be arranged inside the side surfaces of the display panels 100. Accordingly, when the side surfaces of the display panels 100 and the side surfaces of the buffer parts BP are located to be in contact with each other, the lower members (e.g., the bottom chassis CC) may not be visually recognized by the user.

In the present embodiments, when the side surfaces of the display panels 100 and the buffer parts BP of the display devices 10 adjacent to each other are in contact with and abut on each other, an impact may be applied to the side surfaces of the display devices 10 that are coupled to each other during a process of aligning the plurality of display devices 10 on the lower plate LP among the processes of manufacturing the tiled display device TD. In the present embodiments, by locating the buffer parts BP on the lower surfaces of the base parts SUB, an impact that may occur between the display devices 10 located adjacent to each other in the tiling process may be transmitted to not only the display panels 100, but also to the buffer parts BP. Accordingly, an area of a member receiving the impact applied to the side portions of the display devices 10 from the outside of the display devices 10 may be increased, such that there may be an effect of dispersing the impact. Accordingly, the impact concentrated on the edges of the display panels 100 is dispersed, such that damage to the edges of the display panels 100 may be reduced or minimized.

Processes of manufacturing the display device 10 described above will hereinafter be described. In describing processes of manufacturing the display device 10, an overlapping description for the same configuration as that described above with respect to a structure of a plurality of layers of the display device 10 will be omitted or simplified, and processes of manufacturing the display device 10 will be mainly described.

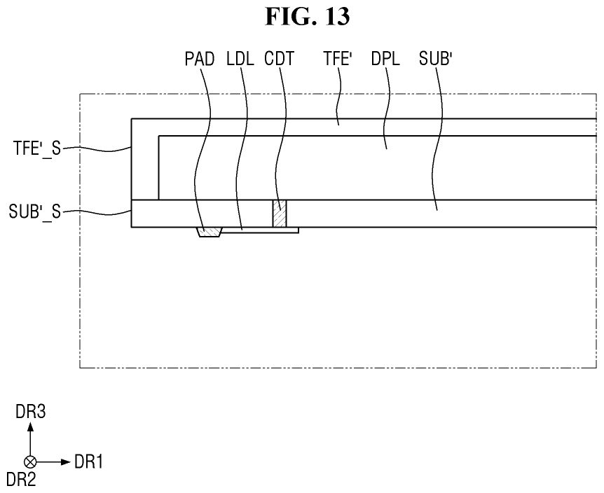

FIGS. 13 to 17 are views illustrating manufacturing processes of the display device of FIG. 11.

First, referring to FIG. 13, a target substrate is prepared. The target substrate may be a mother substrate of the display panel 100. The target substrate may include a first base part SUB′ in which an opening is formed, a display layer DPL formed on the first base part SUB′, a first encapsulation layer TFE′ formed on the display layer DPL, a conductive part CDT located in the opening, a pad part PAD, and a lead line LDL.

The first base part SUB′ and the first encapsulation layer TFE′ may be members corresponding to the base part SUB and the encapsulation layer TFE of the display panel 100 of the display device 10 described above, respectively.

Meanwhile, it has been illustrated in FIG. 13 that a side surface TFE′_S of the first encapsulation layer TFE′ is aligned with a side surface SUB′_S of the first base part SUB′, but the present disclosure is not limited thereto. For example, the first encapsulation layer TFE′ may be located to completely cover an upper surface and the side surface SUB′_S of the first base part SUB′, and the side surface TFE′_S of the first encapsulation layer TFE′ may be arranged outside the side surface SUB′_S of the first base part SUB′.

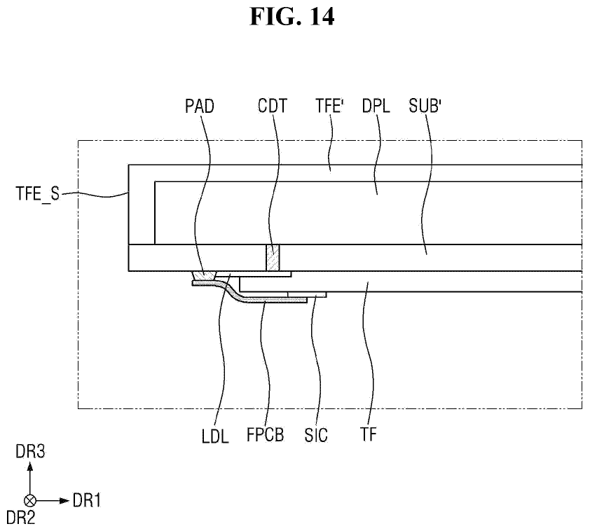

Next, referring to FIG. 14, a heat dissipation member TF, a flexible film FPCB, and a circuit board SIC are located under the first base part SUB′. The order in which the heat dissipation member TF, the flexible film FPCB, and the circuit board SIC are located under the first base part SUB′ is not limited. As an example, the other end of the flexible film FPCB may be electrically connected to the circuit board SIC, one end of the flexible film FPCB may be electrically connected to the pad part PAD, the heat dissipation member TF may be formed on a lower surface of the first base part SUB′, and the circuit board SIC may be then located on a lower surface of the heat dissipation member TF. As another example, the heat dissipation member TF may be formed on the lower surface of the first base part SUB′, the circuit board SIC may be located on a lower surface of the heat dissipation member TF, and both ends of the flexible film FPCB may then be electrically connected to the pad part PAD and the circuit board SIC, respectively.

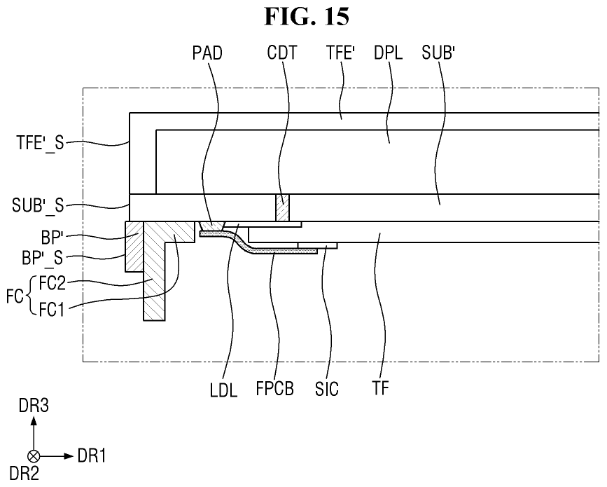

Next, referring to FIG. 15, a lower frame FC and a first buffer part BP′ are formed to surround an edge of the first base part SUB′ while beneath the first base part SUB′. The first buffer part BP′ may be a member corresponding to the buffer part BP of the display device 10 described above.

The lower frame FC and the first buffer part BP′ may be located under the first base part SUB′, and may completely cover the lower surface of the first base part SUB′ at the edge of the first base part SUB′. The first buffer part BP′ may protrude from the edge of the first base part SUB′ to the outside of the first base part SUB′. Accordingly, a side surface BP′_S of the first buffer part BP′ may be arranged outside the side surface SUB′_S of the first base part SUB′ or the side surface TFE′_S of the encapsulation layer TFE′.

The first buffer part BP′ may be attached to a sidewall part FC2 of the lower frame FC through an adhesive member. An upper surface of the first buffer part BP′ and an upper surface of a support part FC1 of the lower frame FC may be positioned on the same plane. The lower frame FC and the first buffer part BP′ may be attached to the lower surface of the first base part SUB′ using a separate adhesive member in a state in which they are coupled to each other.

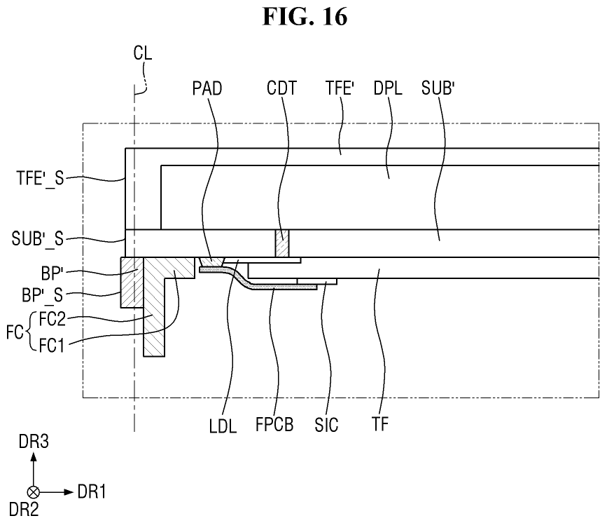

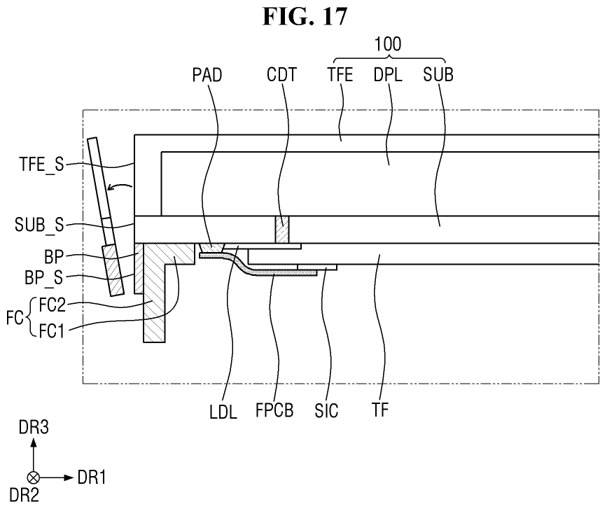

Next, referring to FIGS. 16 and 17, the target substrate is cut along a cutting line CL positioned at an edge of the target substrate. The first base part SUB′ and the first buffer part BP′ are substantially simultaneously or concurrently cut through such a cutting process, such that the base part SUB and the buffer part BP of the display device 10 are formed. The cutting process may be performed using, for example, a laser.

For example, the cutting line CL may be positioned to surround the target substrate, or a portion thereof, along the edge of the target substrate. The cutting line CL may overlap edges of the first base part SUB′, the first buffer part BP′, and the first encapsulation layer TFE′ in the third direction DR3. Edge portions of the first base part SUB′, the first buffer part BP′, and the first encapsulation layer TFE′ may be substantially simultaneously or concurrently cut through the present cutting process. Accordingly, the first base part SUB′, the first buffer part BP′, and the first encapsulation layer TFE′ are cut along the cutting line CL by the laser in the present cutting process, such that side surfaces of the base part SUB, the buffer part BP, and the encapsulation layer TFE may be arranged with each other so as to correspond to the cutting line CL.

Next, a plurality of lower members may be formed in an area partitioned by the sidewall part FC2 of the lower frame FC to manufacture the display device 10 of FIG. 11. For example, the plurality of lower members may include the lower protective layer PC, the protective case SC, the bottom chassis CC, and the like, described above.

In the present embodiments, the process (cutting process) of cutting the first base part SUB′, the first buffer part BP′, and the first encapsulation layer TFE′ of the target substrate has been performed before the plurality of lower member of the display device 10 are formed, but the present disclosure not limited thereto. For example, after the plurality of lower members of the display device 10 are formed, the first base part SUB′, the first buffer part BP′, and the first encapsulation layer TFE′ may be cut along the cutting line CL in the cutting process.

With a method of manufacturing the display device 10 according to the present embodiments, the buffer part BP positioned at the edge of the display panel 100 among the plurality of members located under the display panel 100 may be formed to be aligned with the side surface of the base part SUB. In this case, the side surface SUB_S of the base part SUB and the side surface BP_S of the buffer part BP are aligned with each other as described above, and thus, the impact generated in the tiling process of aligning and fixing the plurality of display devices 10 among the processes of manufacturing the tiled display device TD and applied between the base parts SUB of the adjacent display devices 10 may also be dispersed to the buffer parts BP to reduce or prevent the likelihood of damage to the base parts SUB due to the impact. Accordingly, reliability of the processes of manufacturing the tiled display device TD may be improved. In addition, the lower members located under the display panel 100 do not protrude to the outside of the display panel 100, and it is thus possible to reduce or prevent recognition, by a user, of the lower members located under the display panel 100 in the boundary area SM between the display panels 100.

Hereinafter, other embodiments will be described. In the following embodiments, an overlapping description for the same components as those described above will be omitted or simplified, and components different from those described above will be mainly described.

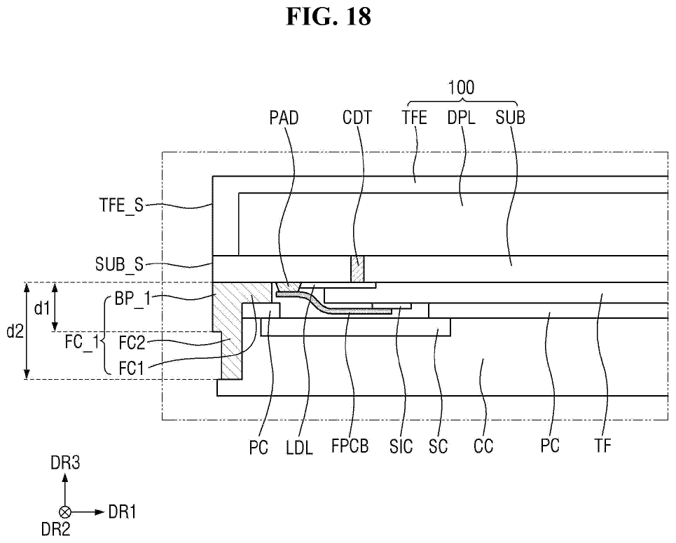

FIG. 18 is an enlarged cross-sectional view illustrating another example of area A of FIG. 4.

Referring to FIG. 18, a display device 10 according to the present embodiments is different from the display device 10 according to the embodiments described above with reference to FIG. 11 in that the buffer part BP_1 is a single member formed integrally with the lower frame FC_1.

In detail, the buffer part BP_1 may be integrated with the lower frame FC_1 to be formed as a single member. The buffer part BP_1 may be integrated with a sidewall part FC2 of the lower frame FC_1. Accordingly, a portion of the lower frame FC_1 extending from a support part FC1 of the lower frame FC_1 and bent in the third direction DR3 may include the buffer part BP_1 having a first length d1 and the sidewall part FC2 having a second length d2. The first length d1 may be smaller than, and may include a portion of, the second length d2. The buffer part BP_1, the sidewall part FC2, and the support part FC1 may include the same material. For example, the buffer part BP_1, the sidewall part FC2, and the support part FC1 may include a material having rigidity (e.g., a predetermined rigidity). For example, the lower frame FC_1 including the buffer part BP_1, the sidewall part FC2, and the support part FC1 may include a metal material such as iron, copper, aluminum, or alloys thereof, but is not limited thereto.

In the present embodiments, the buffer part BP_1 is formed of the same material as the support part FC1 and the sidewall part FC2, and thus, an additional process of locating the buffer part BP_1 outside the sidewall part FC2 of the lower frame FC_1 is omitted, such that manufacturing process efficiency of the display device 10 may be improved. Meanwhile, even though the buffer part BP_1 includes a material that is the same as that of the support part FC1 and the sidewall part FC2 and has rigidity (e.g., a predetermined rigidity), the buffer part BP_1 is formed to be shorter than the length d2 of the sidewall part FC2, and thus, energy for cutting the buffer part BP_1 having the rigidity in the process of cutting the edge portion of the display panel 100 described above may be reduced or minimized.

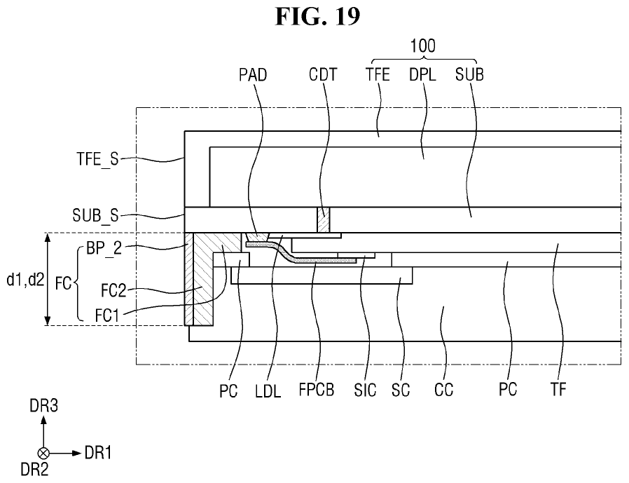

FIG. 19 is an enlarged cross-sectional view illustrating still another example of area A of FIG. 4.

Referring to FIG. 19, a display device 10 according to the present embodiments is different from the display device 10 according to the embodiments described above with reference to FIG. 11 in that the length d1 of the buffer part BP_2 is the same as the length d2 of the sidewall part FC2 of the lower frame FC.

For example, the buffer part BP_2 may completely cover a side surface of the sidewall part FC2 of the lower frame FC. Accordingly, the first length d1 of the buffer part BP_2 may be the same as the second length d2 of the sidewall part FC2 of the lower frame FC.

In the present embodiments, the buffer part BP_2 is located to completely cover the side surface of the sidewall part FC2, such that a contact area between the buffer parts BP_2 of the adjacent display devices 10 may be increased. Accordingly, a buffering effect of dispersing the impact between the adjacent display devices 10 generated in the tiling process of aligning and fixing the plurality of display devices 10 among the processes of manufacturing the tiled display device TD may be improved. Accordingly, reliability of the tiled display device TD including the display devices 10 according to the present embodiments may be improved.

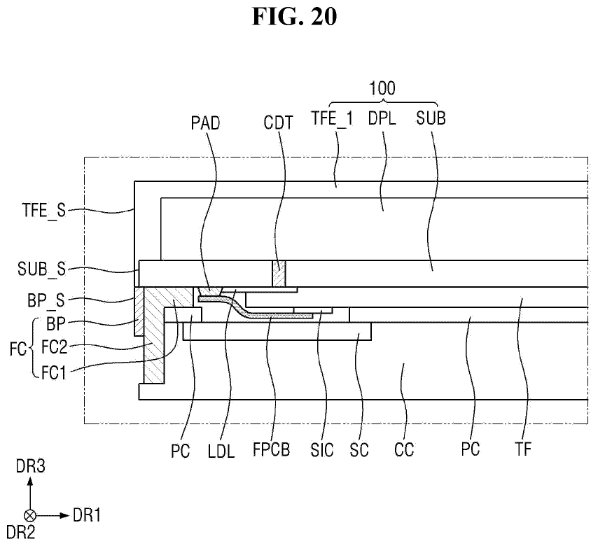

FIG. 20 is an enlarged cross-sectional view illustrating still another example of area A of FIG. 4.

A display device 10 according to the present embodiments is different from the display device 10 according to the embodiments described above with reference to FIG. 11 in that the encapsulation layer TFE_1 of the display panel 100 covers the side surface SUB_S of the base part SUB.

For example, the encapsulation layer TFE_1 of the display panel 100 may cover the upper surface and the side surface of the display layer DPL. In addition, the encapsulation layer TFE_1 may cover the upper surface of the base part SUB exposed by the display layer DPL and the side surface of the base part SUB. Accordingly, the side surface TFE_S of the encapsulation layer TFE_1 may constitute the side surface of the display panel 100.

In the present embodiments, the side surface BP_S of the buffer part BP may be aligned with the side surface of the encapsulation layer TFE_1. Meanwhile, the side surface of the encapsulation layer TFE_1 constitutes the side surface of the display panel 100, such that the side surface SUB_S of the base part SUB may be arranged inside the side surface BP_S of the buffer part BP. Such a structure may be formed by forming the display panel 100 so that the encapsulation layer TFE_1 completely covers the side surface of the base part SUB and then substantially simultaneously or concurrently cutting the encapsulation layer TFE_1 and the buffer part BP, but not cutting the base part SUB in the cutting process of substantially simultaneously or concurrently cutting the display panel 100 and the buffer part BP, in the processes of manufacturing the display device 10.

In the tiled display device TD including the display device 10 according to the present embodiments, the side surface SUB_S of the base part SUB is formed to be completely covered by the encapsulation layer TFE_1, and thus, the buffering effect of dispersing the impact between the adjacent display devices 10 generated in the tiling process of aligning and fixing the plurality of display devices 10 among the processes of manufacturing the tiled display device TD may be further improved. In addition, because the encapsulation layer TFE_1 completely covers the side surface SUB_S of the base part SUB, the upper surface, the side surface, and the lower surface of the edge portion of the base part SUB may be completed covered by the encapsulation layer TFE_1 or the buffer part BP. Accordingly, an area in which the edge portion of the base part SUB is exposed to the outside is reduced or minimized, such that heat dissipation of the display device 10 may be improved.

What is claimed is:

1. A display device comprising:
a display panel comprising a base part, and a display layer on an upper surface of the base part;
a buffer part at an edge of, beneath, and having a side surface that is aligned with a side surface of, the display panel;
a lower frame inside the buffer part, in plan view, beneath the display panel, and comprising a support part for supporting the display panel; and
a pad part beneath a lower surface of the base part and electrically connected to the display layer.

2. The display device of claim 1, wherein the side surface of the buffer part is aligned with a side surface of the base part.

3. The display device of claim 2, wherein the display panel further comprises an encapsulation layer above the base part and covering the display layer, and
wherein the side surface of the buffer part is aligned with a side surface of the encapsulation layer.

4. The display device of claim 1, wherein the display panel further comprises an encapsulation layer above the base part and covering the display layer,
wherein the encapsulation layer covers a side surface of the base part, and
wherein the side surface of the buffer part is aligned with a side surface of the encapsulation layer.

5. The display device of claim 4, wherein the side surface of the base part is inside the side surface of the buffer part in plan view.

6. The display device of claim 1, wherein the buffer part is on an outer side surface of the lower frame.

7. The display device of claim 6, wherein the lower frame further comprises a sidewall part extending from the support part in a downward direction.

8. The display device of claim 6, wherein the buffer part and the lower frame cover the lower surface of the base part at an edge of the base part.

9. The display device of claim 1, wherein the buffer part and the lower frame comprise a same material.

10. The display device of claim 9, wherein the buffer part and the lower frame are formed integrally with each other.

11. The display device of claim 1, wherein the base part comprises polyimide, and
wherein the buffer part has elasticity along a horizontal direction that is substantially perpendicular to a thickness direction of the display panel.

12. The display device of claim 1, further comprising:
a flexible film under the display panel and electrically connected to the pad part; and
a circuit board electrically connected to the flexible film and supporting a driving circuit driving the display layer.

13. The display device of claim 12, wherein the pad part is inside the lower frame.

14. The display device of claim 1, wherein the display layer comprises a connection line on the base part and exposed on a lower surface of the display layer,
wherein the display panel further comprises a conductive part in an opening penetrating through the base part, and electrically connected to the connection line, and
wherein the pad part is electrically connected to the connection line through the conductive part.

15. The display device of claim 14, wherein the opening overlaps the connection line exposed on the lower surface of the display layer.

16. A tiled display device comprising:
a lower plate; and
a plurality of display devices on the lower plate and comprising:
a display panel comprising a base part, and a display layer on an upper surface of the base part;
a buffer part at an edge of the display panel, beneath the display panel, and having a side surface that is aligned with a side surface of the display panel;
a lower frame inside the buffer part under the display panel, and comprising a support part for supporting the display panel; and
a pad part on a lower surface of the base part, and electrically connected to the display layer.

17. The tiled display device of claim 16, wherein the plurality of display devices comprise a first display device and a second display device adjacent to each other,
wherein the buffer part of the first display device and the buffer part of the second display device are in contact with each other, and
wherein the display panel of the first display device and the display panel of the second display device are in contact with each other.

18. The tiled display device of claim 16, wherein the side surface of the buffer part is aligned with a side surface of the base part.

19. The tiled display device of claim 16, wherein the display panel further comprises an encapsulation layer on the base part and covering the display layer, and
wherein the side surface of the buffer part is aligned with a side surface of the encapsulation layer.

20. The tiled display device of claim 16, wherein the buffer part is on an outer side surface of the lower frame, and
wherein the buffer part and the lower frame cover the lower surface of the base part at an edge of the base part.
